(19) United States
(12) Patent Application Publication
(10) Pub. No.: US 2008/0191283 A1
(43) Pub. Date: Aug. 14, 2008

(54) SEMICONDUCTOR DEVICE AND MANUFACTURING METHOD THEREOF

(75) Inventor: Yong Chul Shin, Cheongju-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: HYNIX SEMICONDUCTOR INC., Icheon-si (KR)

(21) Appl. No.: 11/856,696

(22) Filed: Sep. 17, 2007

(30) Foreign Application Priority Data
Feb. 9, 2007 (KR) 2007-13669

(51) Int. Cl. H01L 27/088; H01L 21/8234

(52) U.S. Cl. 257/368; 438/197; 257/E27.06; 257/E21.616

(57) ABSTRACT

A semiconductor device includes a gate pattern formed over a semiconductor substrate, the substrate defining a cell region and a peripheral region. First and second contact plugs are formed in the cell region. Third and fourth contact plugs are formed in the peripheral region. A first separation structure is formed in the cell region and covers the first contact plug. A second separation structures are formed in the peripheral region and define first and second openings, the first opening exposing an upper portion of the third contact plug, the second opening exposing an upper portion of the fourth contact plug. First, second, and third metal wire sections are formed over the first, second, third, and fourth contact plugs. The first metal wire section is formed in the cell region and contacts the second contact plug. The second metal wire section is formed in the peripheral region and contacts the third contact plug. The third metal wire section is formed in the peripheral region and contacts the fourth contact plug. The first separation structure electrically isolates the first contact plug from the first metal section.

### CROSS-REFERENCES TO RELATED APPLICATIONS

The present application claims priority to Korean patent application number 10-2007-013669, filed on Feb. 9, 2007, which is incorporated by reference in its entirety.

### BACKGROUND OF THE INVENTION

The present invention relates to a semiconductor device, and more particularly, to a manufacturing method in which the contact plugs on a cell region and the contact plugs on a peripheral region are formed at substantially the same time reducing the number of processing steps, and an isolation film is formed to isolate the source contact plug and the metal wire of a later step reducing a height of the semiconductor device.

A semiconductor flash memory device includes a plurality of memory cells, select transistors and high voltage transistors. A common flash memory device is configured as a string in which a plurality of memory cells are arranged parallel with each other and on both ends of the string, a configuration in which the select transistors are arranged, is repeated. Here, the memory cell and the select cell are included on the cell region, and the high voltage transistor is included on the peripheral region.

Hereinafter a gate may be referred to as a lower structure and a metal wire formed over a semiconductor device may be referred to as an upper structure. To connect these two structures a contact plug (or via plug) is formed between the lower structure and the upper structure.

The contact plugs that are formed between the select transistors adjoined to each other on a cell region are classified as a source contact plug and a drain contact plug. That is, when the one contact plug formed on one side of a string is a source contact plug, the one contact plug formed on the other side of the string is a drain contact plug.

A contact plug on a peripheral region is directly connected to a high voltage transistor or a bonding region formed on a semiconductor substrate.

Generally, a method for forming a contact plug on a semiconductor substrate is as follows.

First, a first insulation film for isolation of an upper structure and lower structure is formed on a semiconductor substrate on which a plurality of gates is formed. Additionally, to form a source contact plug, a mask is formed over the insulation film with an opening only at the source contact plug region and a source contact hole is formed using an etching process. Subsequently, a metal film is formed to fill entirely the source contact hole such that a source contact plug is formed and then a chemical mechanical polishing process is preformed to expose the first insulation film. Here, the source contact plug is used commonly in a plurality of strings and formed in a line type. Accordingly, for the source contact plug to be isolated from a metal wire, a second insulation film is formed over the source contact plug and the first insulation film.

To form a drain contact plug, a mask is formed over the second insulation film with an opening only at the drain contact plug region and a drain contact hole is formed using an etching process according to the mask pattern. Subsequently, a metal film is formed to entirely fill the drain contact hole, then a chemical mechanical polishing process is preformed to form a contact plug on a peripheral region.

These steps of forming a contact plug are performed separately so that the source contact plug can be isolated from a subsequent metal wire. Therefore, these separate processes increase the number of steps and thus increases fabrication cost and manufacturing time.

### SUMMARY OF THE INVENTION

The present invention relates to a method for manufacturing a semiconductor device in which the numbers of the steps can be decreased by forming a plurality of contact holes at the same time. In addition, a first separation film is formed over a source contact plug such that a later metal wire is isolated from the source contact plug, and a second separation film for separating the contact plug from the metal wires is formed on a peripheral region such that a height of an insulation film for separating the contact plug from the metal wire can be decreased to reduce a height of a device.

In one embodiment, a semiconductor device includes a gate pattern formed over a semiconductor substrate, the substrate defining a cell region and a peripheral region. First and second contact plugs are formed in the cell region. Third and fourth contact plugs are formed in the peripheral region. A first separation structure is formed in the cell region and covers the first contact plug. A second separation structures are formed in the peripheral region and define first and second openings, the first opening exposing an upper portion of the third contact plug, the second opening exposing an upper portion of the fourth contact plug. First, second, and third metal wire sections are formed over the first, second, third, and fourth contact plugs. The first metal wire section is formed in the cell region and contacts the second contact plug. The second metal wire section is formed in the peripheral region and contacts the third contact plug. The third metal wire section is formed in the peripheral region and contacts the fourth contact plug. The first separation structure electrically isolates the first contact plug from the first metal section.

A semiconductor device according to the present invention comprises a gate pattern formed on a semiconductor substrate. A semiconductor device according to the present invention comprises an insulation film that is formed on a semiconductor substrate including the gate pattern, and includes a plurality of contact holes. In addition, the semiconductor device includes a plurality of contact plugs formed inside the contact holes and a first separation film formed over one part of the contact plugs. Additionally, the semiconductor device comprises a second separation film for exposing the other part of the contact plug and defining the region for a metal wire to be formed, and a metal wire formed between the second separation films.

Additionally, the semiconductor device according to the present invention comprises a gate pattern formed over a semiconductor substrate and including word limes, select limes and gate lines, an insulation film formed over the semiconductor substrate including the gate pattern and including a plurality of contact holes, and a plurality of contact plugs formed inside the contact holes, respectively. In addition, the semiconductor device comprises a first separation film formed over the contact plugs that is connected to a source on a cell region among the contact plugs, a second separation film for exposing the contact plugs, among contact plugs, that are connected to a drain on the cell region, a bonding region and the gate line on a peripheral region, respectively, and defining the region for a metal wire to be formed, and a metal wire formed between the second separation films.

The first and second separation films are formed as stacked layers of a nitride film and an oxide film, a width of the first separation film is wider than that of the contact plug on the lower part thereof, and a thickness of the first separation film is shallower than that of the second separation film.

The first separation film separates electrically the contact plug on the lower part thereof from the metal wire.

A method for manufacturing a semiconductor device according to the present invention comprises the steps of forming a gate pattern over a semiconductor substrate, forming an insulation film that on a semiconductor substrate including the gate pattern, forming a plurality of contact holes on the insulation film, forming a plurality of contact plugs inside the contact holes, respectively, forming a first separation film formed over one part of the contact plugs, forming a second separation film for exposing the other part of the contact plug and defining the region for a metal wire to be formed, and forming a metal wire formed between the second separation films.

The method for manufacturing a semiconductor device comprises steps of forming a gate pattern including word limes, select limes and gate lines over a semiconductor substrate, forming an insulation film over the semiconductor substrate including the gate pattern, forming a plurality of contact holes on the insulation film for exposing a source and a drain on a cell region, and the gate line and the bonding region on a peripheral region, respectively, forming contact plugs inside the contact holes, forming a first separation film over the contact plugs that is connected to the source, forming a second separation film for exposing the contact plugs that are connected to the drain, the bonding region and the gate line, respectively, and defining the region for a metal wire to be formed, forming a metal wire formed between the second separation films.

The step of forming the metal wire comprises forming the metal wire to cover the first and second separation films, and performing a chemical and mechanical polishing process to expose the second separation film.

The step of forming the first separation film comprises the steps of forming a nitride film and an oxide film over the insulation film, and remaining the nitride film pattern and the oxide film pattern on a part of the contact plugs among the contact plugs while removing the nitride film pattern and the oxide film pattern on the other part of the contact plugs.

The nitride film is formed in a thickness of 100 to 500 Å and the oxide film is formed in a thickness of 100 to 500 Å.

The step of forming the second separation film comprises the steps of forming a nitride film and an oxide film over the first separation film and the insulation film, and patterning the nitride film and the oxide film for exposing the contact plug except the contact plug below the first separation film and defining the region for the metal wire to be formed.

### BRIEF DESCRIPTION OF THE DRAWINGS

FIGS. 1A to 1I are sectional views showing a method for manufacturing a semiconductor device according to the present invention.

### DESCRIPTION OF SPECIFIC EMBODIMENTS

Embodiments of the present invention will be described in detail with reference to the accompanying drawings.

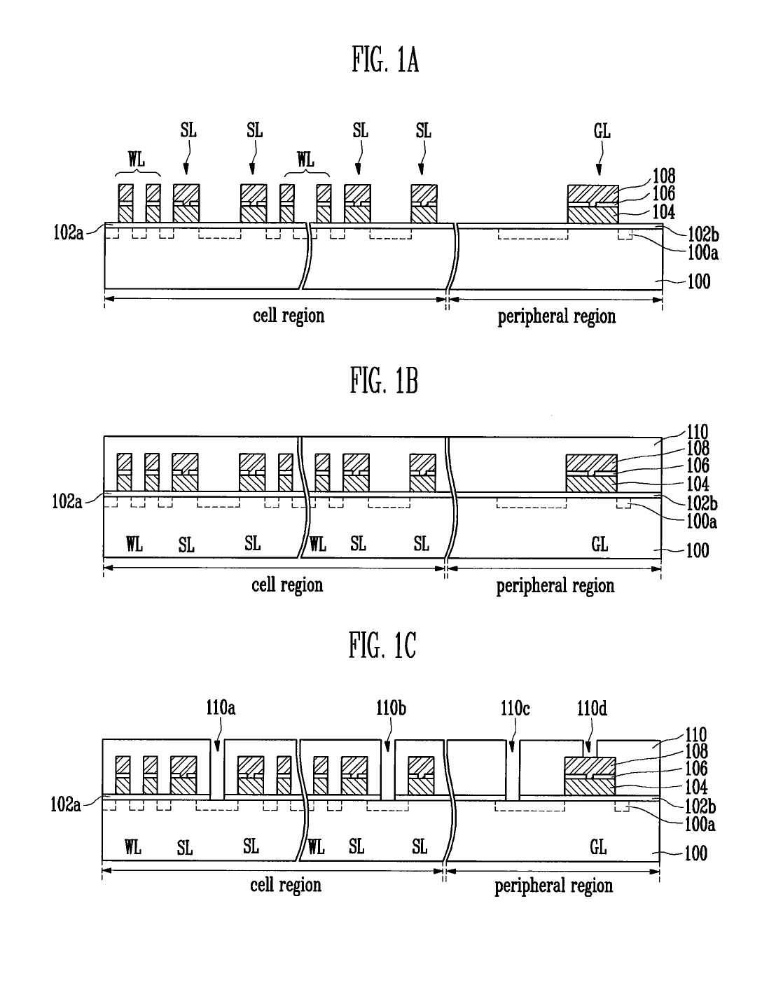

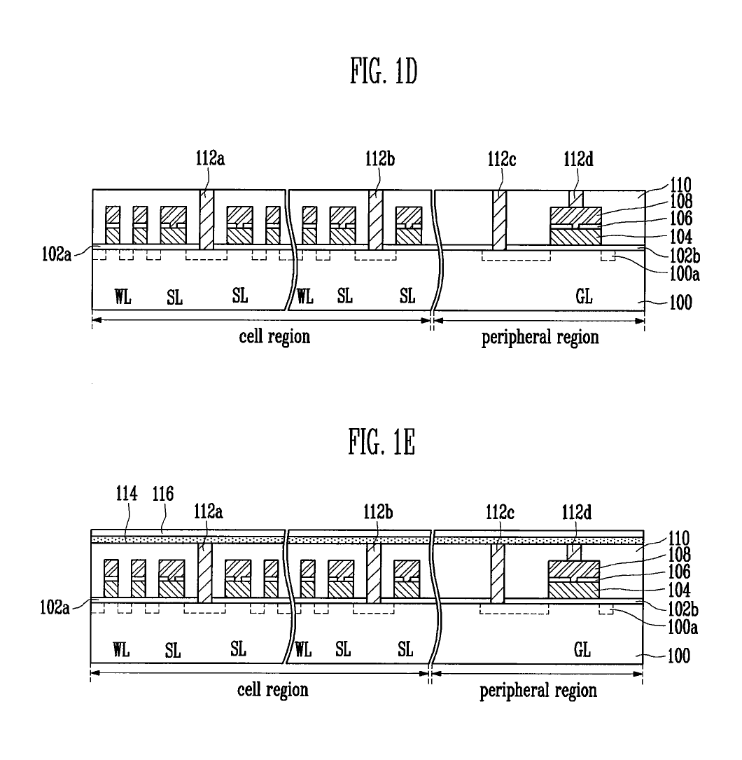

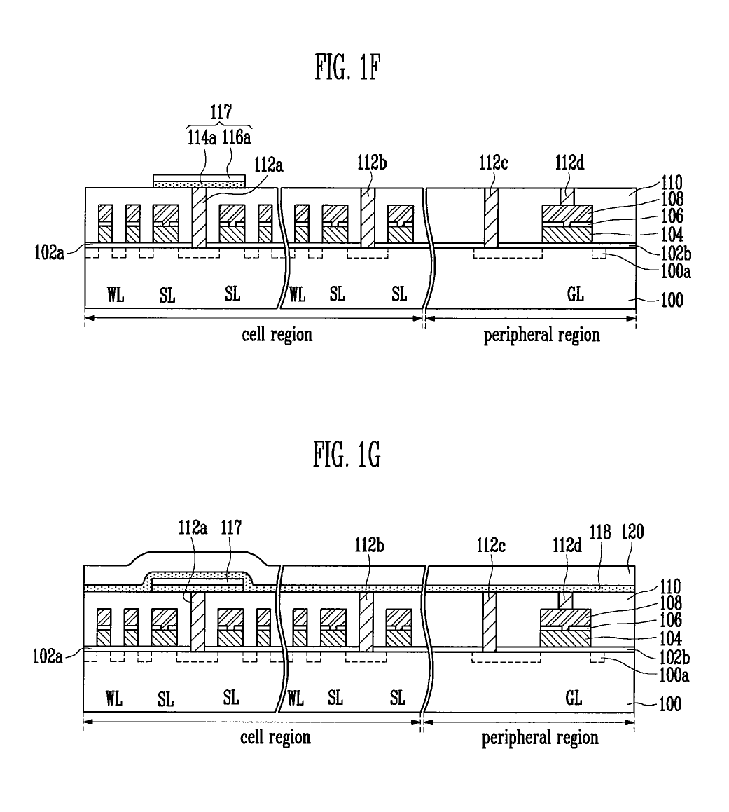

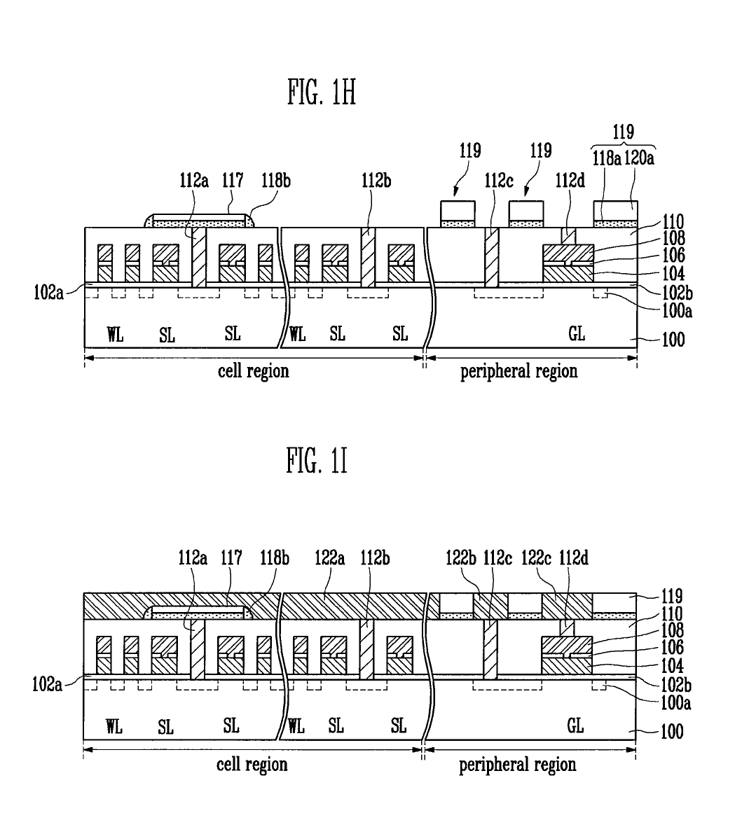

Referring to FIG. 1A, a plurality of word lines (WL) and select lines (SL) are formed on a cell region of a semiconductor substrate 100, and a gate line (GL) is formed on a peripheral region. Here, the select lines include a source select line and a drain select line. The word line (WL) and the select line (SL) include a tunnel insulation film 102a, a floating gate 104, a dielectric film 106 and a control gate 108. A hard mask is formed over the control gate 108. In addition a contact hole is formed on the dielectric film 106 included on the select line (SL), and the floating gate 104 is electrically connected to the control gate 108 through the contact hole on the select line (SL). Meanwhile, a gate insulation film 102b, the floating gate 104, the dielectric film 106 and the control gate 108 are included in the gate line (GL) formed on the peripheral region. Here, a contact hole is formed on the dielectric film 106 included on the gate line (GL). The floating gate 104 is electrically connected to the control gate 108 through the contact hole on the select line (SL). Hereinafter, the word line (WL), the select line (SL), or the gate line (GL), may be referred to a gate pattern.

Subsequently, an ion implantation process is performed to form a bonding region 100a on the semiconductor substrate 100. Here, when an ion implantation process is performed on the cell region and the peripheral region, a mask pattern can be used to implant ions in the desired position.

Referring to FIG. 1B, a first insulation film 110 is formed over the semiconductor substrate 100 and the gate pattern (SL, WL, GL). In addition, a chemical and mechanical polishing (CMP) process is performed to planarize the upper part of the first insulation film 110.

Referring to FIG. 1C, an etching process is performed using a contact mask pattern (not shown) to remove a part of the first insulation film 110 and expose a part of the semiconductor substrate 100. Additionally, first to a fourth contact holes 110a to 110d are formed using an etching process. For example, if the first contact hole 110a is the source contact hole configured to expose a source region between source select lines, the second contact hole 110b is to be the drain contact hole configured to expose a drain region between drain select lines. In addition, the third contact hole 110c on the peripheral region is to be the bonding contact hole to expose the bonding region 100a and the fourth contact hole 110d is to be the gate contact hole to expose the gate line (GL).

Meanwhile, the depth of the fourth contact hole 110d formed over the gate line (GL) on the peripheral region is shallower than the contact holes 110a to 110c such that a second conductive film 108 on the gate line (GL) is over etched. However, the contact hole is to be filled with a metal film in a subsequent process and thus will not adversely affect the operation of the gate line (GL).

Referring to FIG. 1D, a metal film is formed over the first insulation film 110 to fill the contact holes 110a to 110d. A chemical and mechanical polishing (CMP) process is performed to remove part of the metal film and expose the first insulation film 110. As a result, first, second, third, and fourth contact plugs 112a to 112d are formed within the contact holes 110a to 110d.

In one embodiment, the first to the fourth contact plugs 112a to 112d are not all formed at the same time. Referring to FIGS. 1C to 1D, the first and the second contact holes 110a, 110b are formed and then the first and the second contact plugs 112a, 112b are formed. Subsequently, the third and the fourth contact holes 110c, 110d are formed and then the third and the fourth contact plugs 112c, 112d are formed.

Alternatively, the first, second and third contact holes 110a, 110c, 110d are formed at the same time, and then the first, third and fourth contact plugs 112a, 112c, 112d are formed. Subsequently, the second contact hole 110b is formed and then the second contact plug 112b is formed.

Referring to FIG. 1E, a first capping film 114 and a second insulation film 116 are formed to separate a metal wire (to be formed later) and the first contact plug 112a (i.e., source contact plug). The first capping film 114 may be formed using a nitride film and the second insulation film 116 may be formed using a high density plasma (HDP) film. Here, the first capping film 114 may be formed to a thickness of 100 to 500 Å and the second insulation 116 may be formed to a thickness of 100 to 500 Å.

At this time, the second insulation film 116 is used as a buffer film for protecting the first capping film 114 when a separation film is patterned later on a peripheral region. That is, the first capping film 114 serves to insulate the source contact plug 112a from the later metal wire, and the insulation film 116 serves to protect the first capping film 114 from an etching process.

Referring to FIG. 1F, a mask film pattern (not shown) in which the region including the source contact plug 112a is covered, is formed over the second insulation film. An etching process is performed using the mask film pattern (not shown) and then the mask film pattern is removed. A first capping film pattern 114a and the second insulation pattern 116 remain on the region including the source contact plug 112a. Here, the first capping film pattern 114a and the second insulation film pattern 116 serve as a separation structure 117 for the source contact plug 112a to prevent contact with the metal wire to be formed later.

Referring to FIG. 1G, a second capping film 118 and a third insulation film 120 are formed on the semiconductor substrate including the first separation structure 117. Here, the second capping film 118 is used as an etch stop film, and the third insulation film 120 is used for creating separate metal wires. In other words, the second capping film 118 and the third insulation film 120 serve to separate the metal wire on a peripheral region. Accordingly, the second capping film 118 is formed along the surface of the first separation structure 117 and covers all of the first insulation film 110 and the second to fourth contact plugs 112b to 112d. The third insulation film 120 is formed along the surface of the second capping film 118. The second capping film 118 may be formed to a thickness of 200 to 300 Å and the third insulation film 120 may be formed to a thickness of 800 to 1500 Å.

Referring to FIG. 1H, the third insulation film is etched to expose the second, third and fourth contact plugs 112b, 112c, 112d. The first separation structure 117 covers the first contact plug 112a in the cell region. The second capping film remains on a side wall of the first separation structure 117. This is in part because the thickness of the second capping film formed on the side wall tends to be thicker than that formed on a horizontal region. A second separation structure 119, including a third insulation pattern 120a and a second capping film pattern 118a, is defined in the peripheral region.

Referring to FIG. 1I, a metal film is formed over the first insulation film 110 to cover all of the first and second separation structures 117, 119. A chemical mechanical polishing (CMP) is performed on the metal film to divide it into first, second, and third metal wire sections 122a, 122b, and 122c using the second separation structures 119. A first section (or first metal wire) 122a is defined in the cell region. The first separation structure 117 electrically isolates the first contact plug 112a (or source contact plug) from the first metal wire section 122a. The first metal wire section 122a, however, contacts the second contact plug 112b (or drain contact plug) in the cell region. The first metal wire section 122a is a bit line in the present embodiment.

The second metal wire section 122b and the third metal wire section 122c are separated from each other by the second separation structure 119. The second metal wire section 122b contacts the third contact plug 112c in the peripheral region. The third metal wire section 122c contacts the fourth contact plug 112d in the peripheral region.

As described aforementioned, the source contact plug 112a, the drain contact plug 112b and the source contact plugs 112c, 112d on a peripheral region are formed at the same time, and thus the number of manufacturing steps can be decreased. In addition, the first separation film is 117, which is lower in height than the metal wire 122a, is formed over the source contact plug 112a such that the metal wire 122a can easily be separated from the source contact plug 112a.

According to the present invention, a source contact hole, a drain contact hole, and the contact holes on a peripheral region are formed at the same time and thus the number of manufacturing processes for the contact plugs can be decreased. In addition, a separation film is formed partially over the source contact plug such that a metal wire can be separated from the source contact plug. Accordingly, a height of an insulation film between the source contact plug and the metal wire can be decreased and thus a height of entire semiconductor device can be decreased.

What is claimed is:

1. A semiconductor device comprising:
a gate pattern formed over a semiconductor substrate, the substrate defining a cell region and a peripheral region;
first and second contact plugs formed in the cell region;
third and fourth contact plugs are formed in the peripheral region;
a first separation structure formed in the cell region and covering the first contact plug;
a second separation structures formed in the peripheral region and defining first and second openings, the first opening exposing an upper portion of the third contact plug, the second opening exposing an upper portion of the fourth contact plug; and
first, second, and third metal wire sections formed over the first, second, third, and fourth contact plugs, the first metal wire section formed in the cell region and contacting the second contact plug, the second metal wire section formed in the peripheral region and contacting the third contact plug, the third metal wire section formed in the peripheral region and contacting the fourth contact plug,
wherein the first separation structure electrically isolates the first contact plug from the first metal section.

2. A semiconductor device of claim 1, wherein the first separation structure is enclosed by the first metal wire section.

3. A semiconductor device according to claim 1, wherein the first and second separation structures each includes a nitride film and an oxide film.

4. A semiconductor device according to claim 1, wherein a width of the first separation structure is wider than that of the first contact plug.

5. A semiconductor device according to claim 1, wherein a thickness of the first separation structure is less than that of the second separation structure.

6. A semiconductor device according to claim 1, wherein the first separation structure separates electrically the contact plug on the lower part thereof from the metal wire.

7. A semiconductor device according to claim 1, wherein the first contact plug is configured to contact a source region between source select lines, and the second contact plug is configured to contact a drain region between drain select lines.

8. A semiconductor device according to claim 7, wherein the third contact plug is configured to contact a bonding region, and the fourth contact plug is configured to contact a gate line.

9. A semiconductor device comprising:
a gate pattern formed over a semiconductor substrate and including word lines, select lines and gate lines;
an insulation film formed over the semiconductor substrate including the gate pattern and including a plurality of contact holes;
a plurality of contact plugs formed inside the contact holes, respectively;
a first separation structure formed over the contact plugs that is connected to a source on a cell region among the contact plugs;
a second separation structure for exposing the contact plugs in a peripheral region; and
a metal wire formed between the second separation structure and contacting the contact plugs in the peripheral region.

10. A method for manufacturing a semiconductor device comprising the steps of:
forming a gate pattern over a semiconductor substrate;
forming an insulation film that on a semiconductor substrate including the gate pattern;
forming a plurality of contact holes on the insulation film;
forming a plurality of contact plugs inside the contact holes respectively;
forming a first separation film formed over one part of the contact plugs;
forming second separation structures for exposing the other part of the contact plug and defining the region for a metal wire to be formed; and
forming a metal wire formed between the second separation structures.

11. A method for manufacturing a semiconductor device, the method comprising:
forming a gate pattern including word lines, select lines and gate lines over a semiconductor substrate;
forming an insulation film over the semiconductor substrate including the gate pattern;
forming a plurality of contact holes on the insulation film for exposing a source and a drain on a cell region, and the gate line and the bonding region on a peripheral region, respectively;
forming contact plugs inside the contact holes;
forming a first separation structure in the cell region and over the contact plugs that is connected to the source;
forming second separation structures in the peripheral region and configured to expose the contact plugs that are provided in the peripheral region; and
forming a metal wire formed between the second separation structures.

12. A method for manufacturing a semiconductor device according to claim 11, wherein the step of forming the metal wire comprises:
forming the metal wire to cover the first and second separation structures; and
performing a chemical mechanical polishing process to expose the second separation structures.

13. A method for manufacturing a semiconductor device according to claim 11, wherein the step of forming the first separation structure comprises:
forming a nitride film and an oxide film over the insulation film; and
etching the nitride and oxide films to obtain a nitride film pattern and an oxide film pattern directly over the first contact plug.

14. A method for manufacturing a semiconductor device according to claim 13, wherein the nitride film is formed to a thickness of 100 to 500 Å and the oxide film is formed to a thickness of 100 to 500 Å.

15. A method for manufacturing a semiconductor device according to claim 11, wherein the step of forming the second separation structures:
forming a nitride film and an oxide film over the first separation structure and the insulation film; and
patterning the nitride film and the oxide film to expose at least the contact plugs in the peripheral region.
